(19) United States
(12) Patent Application Publication
(10) Pub. No.: US 2025/0336608 A1
(43) Pub. Date: Oct. 30, 2025

(54) FILM CAPACITORS AND CURRENT CONVERSION UNITS HAVING SAME

(71) Applicant: Santak Electronic (Shenzhen) Co., Ltd., Shenzhen (CN)

(72) Inventors: Pingchang Lin, Shenzhen (CN); Jian Wei, Shenzhen (CN); Ping Zhang, Shenzhen (CN)

(21) Appl. No.: 19/186,729

(22) Filed: Apr. 23, 2025

(30) Foreign Application Priority Data
Apr. 26, 2024 (CN) 202420895014.3

(51) Int. Cl. H01G 4/258; H01G 4/224; H01G 4/38; H05K 7/20

(52) U.S. Cl. CPC H01G 4/258; H01G 4/224; H01G 4/38; H05K 7/209

(57) ABSTRACT

A film capacitor and a related current conversion unit is provided. The film capacitor comprises: a capacitor housing having an end wall and a peripheral wall arranged circumferentially along the end wall, wherein the end wall and the peripheral wall collectively enclose an accommodating space of the capacitor housing, and wherein the end wall is configured as a thermally conductive metal wall; a busbar, arranged in the accommodating space of the capacitor housing and having a connection end extending from the accommodating space away from the end wall; a plurality of capacitor cores connected in parallel, arranged in the accommodating space of the capacitor housing and respectively connected to the busbar; and potting compound, filled in the accommodating space of the capacitor housing and separating the plurality of capacitor cores from the thermally conductive metal wall.

### CROSS-REFERENCE TO RELATED APPLICATION

This application claims priority to Chinese Patent Application No. 202420895014.3, filed Apr. 26, 2024, the content of which is hereby incorporated herein by reference in its entirety.

### TECHNICAL FIELD

The present inventive concept relates generally to power supply equipment and, in particular, to film capacitors and current conversion units having same.

### BACKGROUND

In recent years, environmental protection-related markets such as electric vehicles, hybrid electric vehicles, solar and wind power generation systems have expanded rapidly around the world. In such devices, capacitors and power modules are the core system components in motor drive controllers, and these components directly affect the size and lifespan of the controllers. Among various capacitors, film capacitors are more suitable for high-power devices because of their non-polarity, high voltage resistance and high stability.

Traditional film capacitors, such as DC capacitors, can be electrically connected to power semiconductor devices such as IGBT modules and share a heatsink. During operation, the capacitor core of the capacitor generates heat, which is gradually dissipated outward through the capacitor internal potting material, the capacitor housing, and the heatsink, in that order. Generally speaking, the heat dissipation effect is not-ideal.

According to the industry standard for capacitor specifications, the maximum operating temperature of capacitors is generally 105° C., and when the operating temperature exceeds 85° C., derating is required. It can be said that the operating temperature seriously affects the lifespan and application of capacitors.

Therefore, there is a certain demand in the industry to improve capacitors to enhance their heat dissipation capabilities.

### SUMMARY OF THE INVENTION

The present inventive concept provides a film capacitor, which can at least solve some of the above technical problems.

The present inventive concept provides a current conversion unit using the improved film capacitor described above.

According to some embodiments of the present inventive concept, there is provided a film capacitor comprising: a capacitor housing having an end wall and a peripheral wall arranged circumferentially along the end wall, wherein the end wall and the peripheral wall collectively enclose an accommodating space of the capacitor housing, and wherein the end wall is configured as a thermally conductive metal wall; a busbar arranged in the accommodating space of the capacitor housing and having a connection end extending from the accommodating space away from the end wall; a plurality of capacitor cores connected in parallel, arranged in the accommodating space of the capacitor housing and respectively connected to the busbar; and a potting compound filled in the accommodating space of the capacitor housing and separating the plurality of capacitor cores from the thermally conductive metal wall.

The film capacitor, according to some embodiments of the present inventive concept, constructs the end wall of the capacitor housing as a thermally conductive metal wall, enabling heat generated by the capacitor cores during operation to be dissipated through the potting compound and thermally conductive metal wall, and preventing heat accumulation within the film capacitor, which improves heat dissipation efficiency, and extends the service life of the film capacitor. Furthermore, the potting compound completely isolates the capacitor cores from the thermally conductive metal wall, preventing direct contact between the capacitor cores and metal wall that could cause short circuits.

In some embodiments, the peripheral wall of the capacitor housing is configured as a thermally conductive metal wall, and the potting compound separates the plurality of capacitor cores from the end wall and the peripheral wall of the capacitor housing.

The film capacitor, according to some embodiments of the present inventive concept, features both the end wall and peripheral wall of the capacitor housing constructed as thermally conductive metal walls, allowing the heat generated by the capacitor cores to dissipate through the end wall and the peripheral wall, further improving the heat dissipation efficiency and enhancing the working environment of the capacitor core.

In some embodiments, the thermally conductive metal wall is an aluminum wall. The thermally conductive metal wall constructed in this way provides excellent thermal conductivity while maintaining low manufacturing costs.

In some embodiments, the film capacitor further comprises a plurality of heat dissipation fins disposed on the end wall of the capacitor housing, wherein the plurality of heat dissipation fins are arranged in spaced intervals across the entire surface of the end wall.

In some embodiments, at least a portion of the plurality of heat dissipation fins are integrally formed with the capacitor housing, or at least a portion of the plurality of heat dissipation fins are detachably connected to the capacitor housing.

In some embodiments, the busbar includes a first pole and a second pole insulated from each other and each having a connection end, wherein the plurality of capacitor cores each connects its first end to the first pole, and the plurality of capacitor cores each connects its second end to the second pole.

In some embodiments, the first pole and the second pole are arranged opposite to and spaced apart from each other, and the plurality of capacitor cores are arranged between the first pole and the second pole.

In some embodiments, the busbar includes a first pole and a second pole insulated from each other, and further includes a common pole, wherein the first pole, the second pole and the common pole each having a connection end, wherein a first group of capacitor cores among the capacitor cores each connects its first end to the first pole, and a second group of capacitor cores among the capacitor cores each connects its first end to the second pole, and the first group of capacitor cores and the second group of capacitor cores each connects its second end to the common pole.

In some embodiments, the first pole and the second pole are arranged side by side, and the common pole is arranged opposite to and spaced apart from both the first pole and the second pole, wherein the first group of capacitor cores is arranged between the first pole and the common pole, and the second group of capacitor cores is arranged between the second pole and the common pole.

According to further embodiments of the present inventive concept, there is provided a current conversion unit comprising: a unit housing; an electrical network accommodated within the unit housing and configured to convert received current; wherein the electrical network includes the aforementioned film capacitor.

Some of the other features and advantages of the present inventive concept will be apparent to those skilled in the art after reading this application, and the other part will be described in the following specific embodiments in conjunction with the accompanying drawings.

### BRIEF DESCRIPTION OF THE DRAWINGS

The following is a detailed description of the embodiments of the present inventive concept in conjunction with the accompanying drawings.

FIG. 1 is a three-dimensional cross-sectional view of a current conversion unit according to some embodiments the present inventive concept.

FIG. 2 is a planar cross-sectional view of a current conversion unit some embodiments the present inventive concept.

FIG. 3 is a schematic diagram of the film capacitor some embodiments the present inventive concept at one angle.

FIG. 4 is a schematic diagram of the film capacitor shown in FIG. 3 at another angle;

FIG. 5 is a decomposed schematic diagram of the film capacitor some embodiments the present inventive concept.

FIG. 6 is a decomposed schematic diagram of the film capacitor some embodiments the present inventive concept.

### DETAIL DESCRIPTION

Referring now to the accompanying drawings, schematic solutions of the film capacitor and the current conversion unit having the same disclosed by the present inventive concept are described in detail. Although the drawings are provided to present some embodiments of the present inventive concept, the drawings do not have to be drawn according to the dimensions of the specific embodiments, and certain features may be enlarged, removed or partially cut to better illustrate and explain the inventive concept of the present inventive concept. Some components in the drawings can be adjusted in position according to actual needs without affecting the technical effect. The phrase “in the drawings” or similar terms appearing in the specification do not necessarily refer to all drawings or examples.

Certain directional terms used to describe the drawings below, such as “inside”, “outside”, “above”, “below” and other directional terms, will be understood to have their normal meanings and refer to those directions involved when the drawings are normally viewed. Unless otherwise specified, the directional terms described in this specification are basically in accordance with the conventional directions understood by those skilled in the art.

The terms “first”, “first one”, “second”, “second one” and the like used in the present inventive concept do not indicate any order, quantity or importance, but are used to distinguish one component from other components.

The present inventive concept aims to provide a film capacitor, which is suitable for current conversion units such as rectifiers, inverters, DC-DC converters, etc. The film capacitor structures the housing of the capacitor cores so that the end wall (or “bottom wall”) is a thermally conductive metal wall, or the end wall and the peripheral wall arranged around the end wall are both thermally conductive metal walls, so that the heat generated by the capacitor cores during operation can be quickly dissipated through the thermally conductive metal wall, avoiding heat accumulation in the film capacitor, improving the working environment of the capacitor cores, and increasing the working stability and lifespan of the film capacitor.

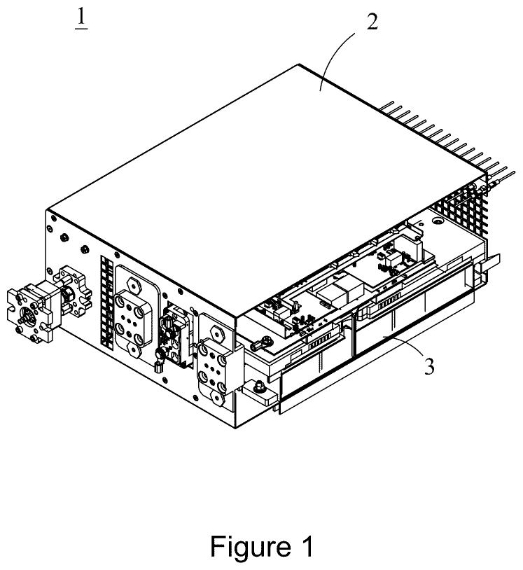

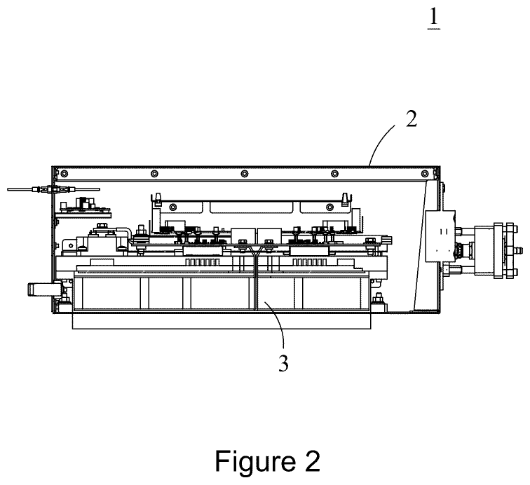

FIG. 1 and FIG. 2 show a current conversion unit 1 using such a film capacitor 3, wherein the current conversion unit 1 is shown in a three-dimensional cross-sectional view (FIG. 1) and a planar cross-sectional view (FIG. 2), and a partial layout inside the unit housing 2 of the current conversion unit 1 is exposed. The unit housing 2 of the current conversion unit 1 contains an electrical network that performs a current conversion function (AC-DC, or DC-AC, or DC-DC), and the electrical network is composed of many electrical components, and the film capacitor 3 is one of the electrical components, which is usually connected to, for example, an IGBT module, a PCB, etc. In some embodiments, the current conversion unit 1 can be a rectifier, an inverter, or a DC-DC converter in a UPS or UPM.

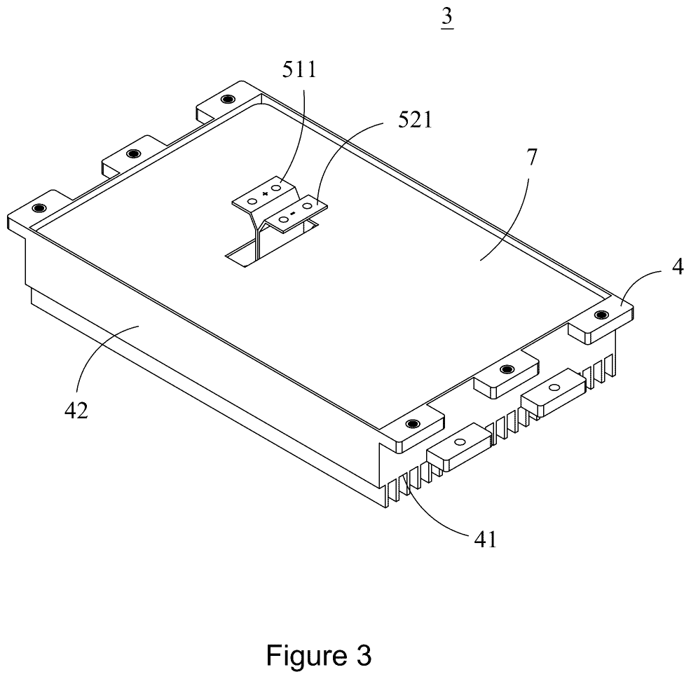

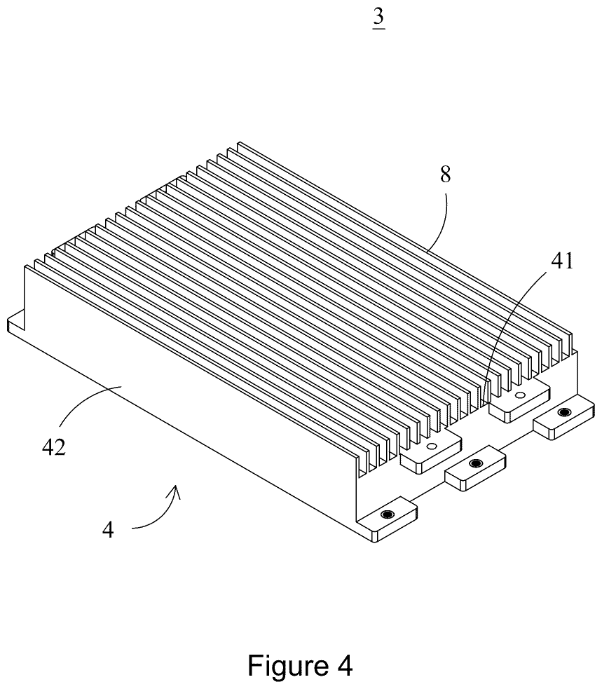

FIG. 3 to FIG. 5 show a film capacitor 3 according to some embodiments of the present inventive concept. As shown in the figures, the film capacitor 3 includes a capacitor housing 4 and elements accommodated in the capacitor housing 4, such as capacitor cores 6. The capacitor housing 4 has an end wall 41 and a peripheral wall 42 arranged circumferentially around the end wall 41. The figure shows that the capacitor housing 4 is constructed in a square shape, and its end wall 41 has four side edges connected in sequence, and the four connected wall segments are sequentially connected to form the peripheral wall 42. The end wall 41 and the peripheral wall 42 are jointly enclosed to form an accommodating space 43 of the capacitor housing 4. Of course, the configuration of the capacitor housing 4 can have other deformations to adapt to different installation environments. In some embodiments, the end wall 41 of the capacitor housing 4 is made of a heat-conducting metal material, thereby forming a thermally conductive metal wall. Such an end wall 41 allows the heat generated by the capacitor cores 6 during operation to be quickly discharged, thereby improving the heat dissipation efficiency. The peripheral wall 42 can be made of plastic. In some embodiments, the end wall 41 and the peripheral wall 42 are both thermally conductive metal walls made of a heat-conducting metal material, which can further improve the heat dissipation efficiency of the capacitor cores 6. Any suitable heat-conducting metal material, such as aluminum or copper, can be selected to prepare the thermally conductive metal wall.

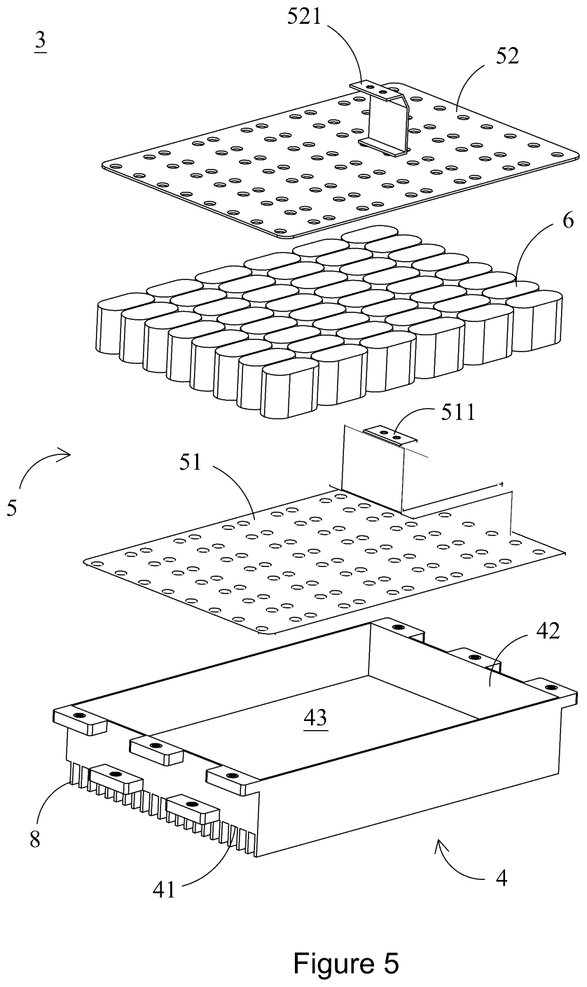

The capacitor cores 6 and the busbar 5 are both fixedly arranged in the accommodating space 43 of the capacitor housing 4. As shown in FIG. 5, a plurality of capacitor cores 6 are arranged in an array and connected in parallel in the electrical network of the current conversion unit 1. The busbar 5 is used to connect each capacitor core 6 to other devices, such as a PCB. In the illustrated embodiments, the busbar 5 includes a first pole 51 and a second pole 52, each of which is plate-shaped and has a plurality of junctions. The first pole 51 and the second pole 52 are opposite each other and spaced apart, wherein the first pole 51 is closer to the end wall 41 of the capacitor housing 4 than the second pole 52. The capacitor cores 6 are arranged between the first pole 51 and the second pole 52, and each capacitor core 6 is connected to the first pole 51 at one end and to the second pole 52 at the other end. An insulating layer 54 is provided between the first pole 51 and the second pole 52 to isolate the first pole 51 from the second pole 52 to prevent the first pole 51 from forming a short circuit with the second pole 52. One of the first pole 51 and the second pole 52 can be a positive pole, and the other can be a negative pole. The first pole 51 has a first connection end 511 extending away from the end wall 41 and out of the capacitor housing 4, and the second pole 52 has a second connection end 521 extending away from the end wall 41 and out of the capacitor housing 4. Through the first connection end 511 and the second connection end 521 of the busbar 5, the film capacitor 3 can be connected to other devices.

After the capacitor cores 6 and the busbar 5 are arranged in the accommodating space 43 of the capacitor housing 4, a sealing and insulating potting compound 7, such as epoxy resin, is filled into the accommodating space 43. The potting compound 7 packages all the capacitor cores 6, separates these capacitor cores 6 from the thermally conductive metal wall of the capacitor housing 4, and prevents them from directly contacting and forming a short circuit. In the illustrated embodiments, the potting compound 7 packages both the capacitor cores 6 and the busbar 5 in the accommodating space 43 of the capacitor housing 4, and only the first connection end 511 and the second connection end 521 of the busbar 5 are exposed. The capacitor housing 4 can be open on the side opposite to the end wall 41, and after the capacitor cores 6 and the busbar 5 and other components are installed through the open side, a flat surface is constructed on the open side by the potting compound 7. The heat generated by the capacitor cores 6 during operation is dissipated through the potting compound 7 and the thermally conductive metal wall layer by layer, and the heat dissipation efficiency is significantly improved compared with the traditional housing.

In addition, a plurality of heat dissipation fins 8 may be arranged on the end wall 41 of the capacitor housing 4, each heat sink 8 being substantially perpendicular to the end wall 41, and all heat dissipation fins 8 may be evenly spaced and arranged on the entire surface of the end wall 41. After passing through the thermally conductive metal wall, the heat of the capacitor cores 6 is further conducted by the heat dissipation fins 8 and quickly leaves the film capacitor 3. The heat dissipation fins 8 may be integrally formed with the capacitor housing 4 or may be detachably mounted on the end wall 41 of the capacitor housing 4.

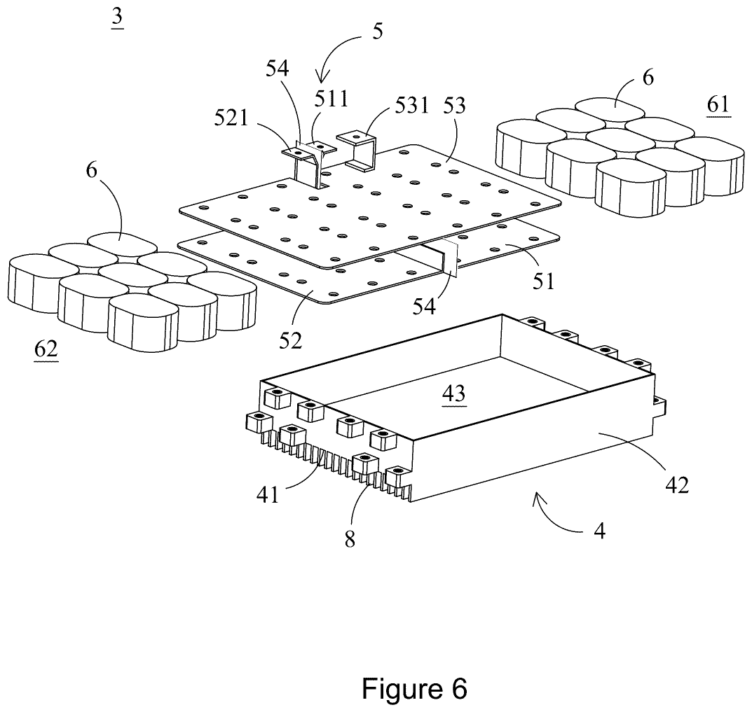

FIG. 6 shows a film capacitor 3 according to some embodiments of the present inventive concept. Similar to the embodiments discussed above, the film capacitor 3 may also include a capacitor housing 4 and elements accommodated in the capacitor housing 4, such as capacitor cores 6. The capacitor housing 4 has an end wall 41 and a peripheral wall 42 arranged circumferentially around the end wall 41. The figure shows that the capacitor housing 4 is constructed in a square shape, and its end wall 41 has four side edges connected in sequence, and the four connected wall segments are connected in sequence to form a peripheral wall 42, so that the end wall 41 and the peripheral wall 42 jointly enclose a accommodating space 43 of the capacitor housing 4. Of course, the configuration of the capacitor housing 4 can have other deformations to adapt to different installation environments. In some embodiments, the end wall 41 of the capacitor housing 4 is made of a heat-conducting metal material, thereby forming a thermally conductive metal wall. Such an end wall 41 allows the heat generated by the capacitor cores 6 during operation to be quickly discharged, thereby improving the heat dissipation efficiency. The peripheral wall 42 can be made of plastic. In further embodiments, the end wall 41 and the peripheral wall 42 are both made of heat-conducting metal materials, which can further improve the heat dissipation efficiency of the capacitor cores 6. Any suitable heat-conducting metal material, such as aluminum or copper, can be selected to prepare the thermally conductive metal wall.

The capacitor cores 6 and the busbar 5 are both fixedly arranged in the accommodating space 43 of the capacitor housing 4. As shown in FIG. 6, the multiple capacitor cores 6 of the film capacitor 3 are divided into two groups, namely the first group of capacitor cores 61 and the second group of capacitor cores 62, each group of capacitor cores is arranged in an array and connected in parallel to the electrical network of the current conversion unit 1. The busbar 5 is used to connect each capacitor core 6 to other devices, such as a PCB. In the embodiments shown, the busbar 5 includes a first pole 51, a second pole 52 and a common pole 53, each of which is plate-shaped and has a plurality of junctions. The first pole 51 and the second pole 52 are arranged side by side and are closer to the end wall 41 of the capacitor housing 4 than the common pole 53. In some embodiments, the first pole 51 and the second pole 52 can be substantially in the same horizontal plane. The common pole 53 is arranged opposite to and spaced apart the first pole 51 and the second pole 52, so that an accommodating compartment is formed respectively between the first pole 51 and the common pole 53, and between the second pole 52 and the common pole 53. The first group of capacitor cores 61 is arranged in a compartment formed by the first pole 51 and the common pole 53, and each capacitor core 6 in the first group of capacitor cores 61 is connected to the first pole 51 at one end and to the common pole 53 at the other end. The second group of capacitor cores 62 is arranged in a compartment formed by the second pole 52 and the common pole 53, and each capacitor core 6 in the second group of capacitor cores 62 is connected to the second pole 52 at one end and to the common pole 53 at the other end. An insulating layer 54 is provided between the first pole 51 and the second pole 52 to isolate the first pole 51 from the second pole 52 to prevent the first pole 51 and the second pole 52 from forming a short circuit. The insulating layer 54 also isolates the common pole 53 from the first pole 51 and the second pole 52. One of the first pole 51 and the second pole 52 may be a positive pole, and the other may be a negative pole. The first pole 51 has a first connection end 511 extending away from the end wall 41 and out of the capacitor housing 4, the second pole 52 has a second connection end 521 extending away from the end wall 41 and out of the capacitor housing 4, and the common pole 53 has a third connection end 531 extending away from the end wall 41 and out of the capacitor housing 4. Through the first connection end 511, the second connection end 521 and the third connection end 531 of the busbar 5, the film capacitor 3 can be connected to other devices, such as a PCB.

After the capacitor cores 6 and the busbar 5 are arranged in the accommodating space 43 of the capacitor housing 4, a sealing and insulating potting compound 7, such as epoxy resin, is filled into the accommodating space 43. The potting compound 7 packages all the capacitor cores 6, separates these capacitor cores 6 from the thermally conductive metal wall of the capacitor housing 4, and prevents them from directly contacting and forming a short circuit. In the illustrated embodiments, the potting compound 7 packages both the capacitor cores 6 and the busbar 5 in the accommodating space 43 of the capacitor housing 4, and only the first connection end 511, the second connection end 521 and the third connection end 531 of the busbar 5 are exposed. The capacitor housing 4 can be open on the side opposite to the end wall 41, and after the capacitor cores 6 and the busbar 5 and other components are installed through the open side, a flat surface is constructed on the open side by the injected potting compound 7. The heat generated by the capacitor cores 6 during operation is dissipated layer by layer through the potting compound 7 and the thermally conductive metal wall, and the heat dissipation efficiency is significantly improved compared with the traditional housing.

In addition, a plurality of heat dissipation fins 8 may be arranged on the end wall 41 of the capacitor housing 4, each heat sink 8 being substantially perpendicular to the end wall 41, and all heat dissipation fins 8 may be evenly spaced and arranged on the entire surface of the end wall 41. After passing through the thermally conductive metal wall, the heat of the capacitor cores 6 is further conducted by the heat dissipation fins 8 and quickly leaves the film capacitor 3. The heat dissipation fins 8 may be integrally formed with the capacitor housing 4 or may be detachably mounted on the end wall 41 of the capacitor housing 4.

It should be understood that although this specification is described according to various embodiments, not every embodiment contains only one independent technical solution. This description of the specification is only for the sake of clarity. Those skilled in the art should regard the specification as a whole. The technical solutions in each embodiment can also be appropriately combined to form other implementation methods that can be understood by those skilled in the art.

The above description is only an illustrative specific implementation method of the present inventive concept and is not intended to limit the scope of the present inventive concept. Any equivalent changes, modifications and combinations made by any technician in the field without departing from the concept and principle of the present inventive concept shall fall within the scope of protection of the present inventive concept.

What is claimed is:

1. A film capacitor, wherein it comprises:
a capacitor housing having an end wall and a peripheral wall arranged circumferentially along the end wall, wherein the end wall and the peripheral wall enclose an accommodating space of the capacitor housing, and wherein the end wall is configured as a thermally conductive metal wall;
a busbar arranged in the accommodating space of the capacitor housing and having a connection end extending from the accommodating space away from the end wall;
a plurality of capacitor cores connected in parallel, arranged in the accommodating space of the capacitor housing and respectively connected to the busbar; and
potting compound filled in the accommodating space of the capacitor housing and separating the plurality of capacitor cores from the thermally conductive metal wall.

2. The film capacitor of claim 1, wherein the peripheral wall of the capacitor housing is constructed as a thermally conductive metal wall, and the potting compound separates the plurality of capacitor cores from the end wall and the peripheral wall of the capacitor housing.

3. The film capacitor of claim 1, wherein the thermally conductive metal wall is an aluminum wall.

4. The film capacitor of claim 1, wherein the film capacitor further comprises a plurality of heat dissipation fins disposed on the end wall of the capacitor housing, wherein the plurality of heat dissipation fins are arranged in spaced intervals across an entire surface of the end wall.

5. The film capacitor of claim 4, wherein at least a portion of the plurality of heat dissipation fins is integrally formed with the capacitor housing, or at least a portion of the plurality of heat dissipation fins is detachably connected to the capacitor housing.

6. The film capacitor of claim 1, wherein the busbar comprises a first pole and a second pole insulated from each other and each have a connection end, wherein the plurality of capacitor cores each connects its first end to the first pole, and the plurality of capacitor cores each connects its second end to the second pole.

7. The film capacitor of claim 6, wherein the first pole and the second pole are arranged opposite to and spaced apart from each other, and the plurality of capacitor cores are arranged between the first pole and the second pole.

8. The film capacitor of claim 1, wherein the busbar comprises a first pole and a second pole insulated from each other, and further comprises a common pole, wherein the first pole, the second pole and the common pole each have a connection end, wherein a first group of capacitor cores among the plurality of capacitor cores each connects its first end to the first pole, and a second group of capacitor cores among the plurality of capacitor cores each connects its first end to the second pole, and the first group of capacitor cores and the second group of capacitor cores each connects its second end to the common pole.

9. The film capacitor of claim 8, wherein the first pole and the second pole are arranged side by side, and the common pole is arranged opposite to and spaced apart from both the first pole and the second pole, wherein the first group of capacitor cores is arranged between the first pole and the common pole, and the second group of capacitor cores is arranged between the second pole and the common pole.

10. A current conversion unit, comprising:
a unit housing; and
an electrical network accommodated within the unit housing and configured to convert received current,
the electrical network comprises a film capacitor as claimed in claim 1.
